(19) United States
(12) Patent Application Publication
(10) Pub. No.: US 2003/0178917 A1
(43) Pub. Date: Sep. 25, 2003

(54) Piezoceramic bending converter

(76) Inventors: Herbert Hofmann, Redwitz (DE); Renate Hofmann, Redwitz (DE); Michael Riedel, Roedental (DE); Andreas Schmid, Michelau (DE)

Correspondence Address: HARNESS, DICKEY & PIERCE, P.L.C., P.O.BOX 8910, RESTON, VA, 20195, US

(21) Appl. No.: 10/240,841

(22) PCT Filed: Apr. 3, 2001
(86) PCT No.: PCT/DE01/01299

(30) Foreign Application Priority Data
Apr. 4, 2000 (DE) 10016621.0

(51) Int. Cl. H01L 41/08

(52) U.S. Cl. 310/330

(57) ABSTRACT

A piezoceramic bending converter (1) provided with a flat supporting body (2) and a polarized lead zirconate titanium piezoceramic (3) applied to at least one side of said supporting body. For low thermal self deformation, a nickel/cobalt/iron alloy, nickel/iron alloy and a silicon/germanium semi-material are used as materials for the supporting body (2), wherein the thermal expansion coefficient of the supporting body (2) is adapted to that of the piezoceramic (3).

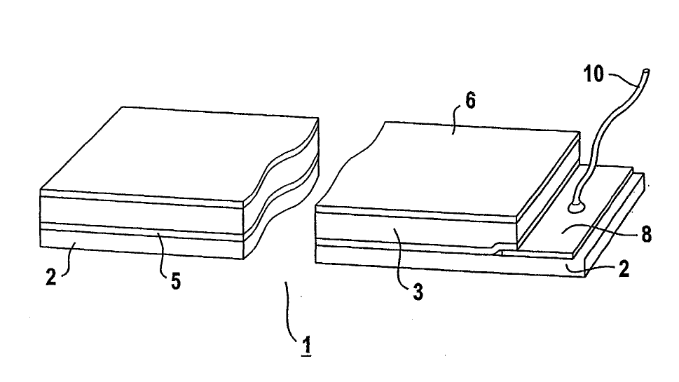

The invention relates to a piezoceramic bending transducer having a flat support body and a polarized piezoceramic which is applied to at least one side of the support body and comprises lead, zirconium and titanium, the coefficient of thermal expansion of the support body being matched to the coefficient of thermal expansion of the polarized piezoceramic.

A bending transducer of this type is known, for example, from WO 96/41384 A1. Glass or the piezoceramic itself is proposed for use as material for the support body.

The piezoceramic bending transducer described in the introduction, with a piezoceramic applied to a flat support body, serves primarily to exploit the indirect or reciprocal piezoelectric effect, i.e. to convert electrical energy into mechanical energy. There is a wide range of technical applications for the bending transducer. Examples of these applications are as a piezoelectric print head for an ink-jet printer, as an actuator in Braille lines in reading equipment for the blind, in textile machines or in valves.

A bending transducer with the matching of the coefficient of thermal expansion of support body and piezoceramic mentioned in the introduction is particularly suitable for applications in valves, in particular in pneumatic valves. This is because when used in this way, even slight inherent thermal bending of a few μm/10° K caused by different expansion coefficients of support body and piezoceramic is no longer tolerable. This is because even such slight inherent thermal bending of the bending transducer in the event of a temperature change would mean that the closing function of the valve, for example, is no longer ensured.

The coefficient of thermal expansion of a piezoceramic comprising lead, zirconium and titanium, also known as a PZT piezoceramic, fluctuates between −5 and +6·10⁻⁶/K as a function of the degree of polarization and of the direction of the electrical field used for actuation. Therefore, the coefficient of thermal expansion of the PZT ceramic differs according to the way in which it has been produced and the way in which it is actuated. On the other hand, differing proportions by weight of the individual components of a PZT piezoceramic only lead to the expansion coefficient of the piezoceramic fluctuating by ±0.5·10⁻⁶/K.

However, if, according to WO 96/41384 A1, glass is used as material for the support body, the coefficient of thermal expansion of the piezoceramic nevertheless differs from the coefficient of thermal expansion of the glass, depending on the polarization of the piezoceramic, to such an extent that the use of a bending transducer of this type is no longer tolerable in a valve, in particular in a pneumatic valve, on account of the inherent thermal bending which is to be expected. The same is true of the use of a piezoceramic as material for the support body, since the polarization of the PZT piezoceramic of the active layer results in a coefficient of thermal expansion of the PZT piezoceramic which differs from the coefficient of thermal expansion of the support body.

It is an object of the invention to provide a piezoceramic bending transducer of the type described in the introduction which has an inherent thermal bending which is reduced further compared to the prior art.

According to the invention, in a first alternative this object is achieved by the fact that the support body consists of a nickel/cobalt/iron alloy which comprises 28-30% by weight of nickel, 16-18% by weight of cobalt, 0-3% by weight of at least one element selected from the group consisting of carbon, manganese and silicon, remainder iron.

In a second alternative, the object, for a piezoceramic bending transducer of the type described in the introduction, is achieved, according to the invention, by the fact that the support body consists of a nickel/iron alloy which comprises 40-44% by weight of nickel, 0-3% by weight of at least one element selected from the group consisting of cobalt, chromium, carbon, manganese, phosphorus, sulfur, silicon and aluminum, remainder iron.

In a third alternative, the object is achieved, for a piezoceramic bending transducer of the type described in the introduction, according to the invention, by the fact that the support body consists of a semiconductor material which comprises 10-55% by weight of silicon, 45-90% by weight of germanium, remainder trace elements. The trace elements should be present in a quantity which is as low as possible.

The invention is based on the consideration that a PZT piezoceramic has a coefficient of thermal expansion of between 4 and 5·10⁻⁶/K irrespective of its composition in the finished bending transducer. Furthermore, the invention is based on the consideration that it should be possible to match any value for the coefficient of thermal expansion within this range by using a corresponding composition of the material of the support body. Adjusting the coefficient of thermal expansion of the material of the support body to the coefficient of thermal expansion of the PZT piezoceramic in this way can be achieved by means of a nickel/cobalt/iron alloy as a result of the proportions by weight of nickel and cobalt being adjusted and by the optional addition of the further constituents mentioned.

Alternatively, this is also made possible by means of the proportions by weight of nickel in a nickel/iron alloy and the addition of certain proportions by weight of the further constituents mentioned.

Finally, this is made possible by adjusting the proportions by weight of silicon and germanium in a semiconductor material which contains silicon and germanium, possibly with a residual doping of trace elements.

The coefficient of thermal expansion of the material of the support body can be adjusted within the fluctuation range of the coefficient of thermal expansion of the PZT piezoceramic by means of the proportions of the respective components which are listed in patent claims 1 to 3. This allows the coefficient of thermal expansion of the PZT piezoceramic in the polarized state and the coefficient of thermal expansion of the material of the support body to be matched as far as possible.

An exemplary embodiment of the invention is explained in more detail with reference to a drawing.

In the drawing, the only FIGURE shows a piezoceramic bending transducer 1 with a support body 2 and a layer of a lead-zirconate-titanium piezoceramic 3 applied to one side of the support body. The piezoceramic 3 is covered with an inner electrode 5, which faces the support body 2, and with an outer electrode 6. Both electrodes 5 and 6 are applied to the surfaces of the piezoceramic 3 as metallization layers comprising silver-palladium.

The lead-zirconate-titanium piezoceramic 3 has been polarized by means of the electrodes 5 and 6. The piezoceramic 3 is actuated by the application of a voltage between the inner electrode 5 and the outer electrode 6. The support body 2 consists of a nickel/cobalt/iron alloy which comprises 28.5% by weight of nickel, 18% by weight of cobalt, 0.25% by weight of manganese and 0.25% by weight of silicon, remainder iron.

To make electrical contact with the inner electrode 5, a small copper plate 8 is adhesively bonded to the free end of the support body 2, this small copper plate 8 being partially inserted between the support body 2 and the inner electrode 5. The small copper plate 8 makes it easy to make contact with a connection wire 10 by soldering.

To operate the illustrated bending transducer 3, which is also known as a unimorph bending transducer 3, on account of the piezoceramic 3 being applied to only one side, a potential is applied to the connection 10. In this case, the outer electrode 6 is applied to ground potential.

For reasons of clarity, the materials listed in patent claims 2 and 3 for the support body 2 are not illustrated in further figures.

1. A piezoceramic bending transducer (1) having a flat support body (2) and a polarized piezoceramic (3) which is applied to at least one side of the support body (2) and comprises lead, zirconium and titanium, the coefficient of thermal expansion of the support body (2) being matched to the coefficient of thermal expansion of the polarized piezoceramic (3), characterized in that the support body (2) consists of a nickel-cobalt-iron alloy, comprising 28-30% by weight of nickel, 16-18% by weight of cobalt, 0-3% by weight of at least one element selected from the group consisting of carbon, manganese and silicon, remainder iron.

2. A piezoceramic bending transducer (1) having a flat support body (2) and a polarized piezoceramic (3) which is applied to at least one side of the support body (2) and comprises lead, zirconium and titanium, the coefficient of thermal expansion of the support body (2) being matched to the coefficient of thermal expansion of the polarized piezoceramic (3), characterized in that the support body (2) consists of a nickel-iron alloy, comprising 40-44% by weight of nickel, 0-3% by weight of at least one element selected from the group consisting of cobalt, chromium, carbon, manganese, phosphorus, sulfur, silicon and aluminum, remainder iron.

3. A piezoceramic bending transducer (1) having a flat support body (2) and a polarized piezoceramic (3) which is applied to at least one side of the support body (2) and comprises lead, zirconium and titanium, the coefficient of thermal expansion of the support body (2) being matched to the coefficient of thermal expansion of the polarized piezoceramic (3), characterized in that the support body (2) consists of a semiconductor material comprising 10 to 55% by weight of silicon, 45-90% by weight of germanium, remainder trace elements.
